(19) United States
(12) Patent Application Publication
(10) Pub. No.: US 2024/0210529 A1
(43) Pub. Date: Jun. 27, 2024

(54) PHOTODETECTOR AND DISTANCE MEASUREMENT APPARATUS

(71) Applicant: SONY SEMICONDUCTOR SOLUTIONS CORPORATION, KANAGAWA (JP)

(72) Inventor: YUSUKE MATSUMURA, KANAGAWA (JP)

(21) Appl. No.: 18/557,573

(22) PCT Filed: Mar. 3, 2022
(86) PCT No.: PCT/JP2022/009234

§ 371 Date: Oct. 26, 2023

(30) Foreign Application Priority Data
May 20, 2021 (JP) 2021-085631

(51) Int. Cl. G01S 7/481; G01S 7/4865; G01S 17/10; H01L 23/00; H01L 27/146

(52) U.S. Cl. CPC G01S 7/4816; G01S 7/4865; G01S 17/10; H01L 24/08; H01L 27/14627; H01L 27/1463; H01L 27/14634; H01L 27/14649; H01L 2224/08145

(57) ABSTRACT

A photodetector according to an embodiment of the present disclosure includes a first substrate, a second substrate, a first electrode, and a second electrode. The first substrate has a first surface serving as a light receiving surface and a second surface opposed to the first surface, and has a plurality of pixels disposed in an arrayed manner. The first substrate includes a light receiving section provided for each of the pixels. The light receiving section generates, through photoelectric conversion, electric charge corresponding to the amount of received light. The second substrate is disposed on a side of the second surface of the first substrate, has a third surface directly opposed to the second surface, and also has a fourth surface opposed to the third surface. The second substrate has a band gap wider than a band gap of the first substrate. The second substrate includes a multiplication section provided for each of the pixels. The multiplication section applies avalanche multiplication to the electric charge generated at the light receiving section. The first electrode is provided at the first surface of the first substrate and is electrically coupled to the light receiving section. The second electrode is provided at the fourth surface of the second substrate and is electrically coupled to the multiplication section.

### TECHNICAL FIELD

The present disclosure relates, for example, to a photodetector using an avalanche photodiode, and a distance measurement apparatus including the photodetector.

### BACKGROUND ART

For example, Patent Literature 1 discloses a light receiving element that includes a first photoelectric conversion element and a second photoelectric conversion element on a principal surface of a silicon semiconductor substrate. The first photoelectric conversion element includes silicon. The second photoelectric conversion element includes a semiconductor material having a band gap narrower than that of silicon.

### CITATION LIST

### Patent Literature

Patent Literature 1: Japanese Unexamined Patent Application Publication No. 2018-032810

### SUMMARY OF THE INVENTION

Incidentally, it is desired that a photodetector included in a distance measurement apparatus or the like achieve improved sensitivity at near-infrared and short-wave infrared wavelengths and reduced occurrence of noise.

It is desirable to provide a photodetector and a distance measurement apparatus that make it possible to reduce occurrence of noise while improving the sensitivity at near-infrared and short-wave infrared wavelengths.

A photodetector according to an embodiment of the present disclosure includes a first substrate, a second substrate, a first electrode, and a second electrode. The first substrate has a first surface serving as a light receiving surface and a second surface opposed to the first surface, and has a plurality of pixels disposed in an arrayed manner. The first substrate includes a light receiving section provided for each of the pixels. The light receiving section generates, through photoelectric conversion, electric charge corresponding to the amount of received light. The second substrate is disposed on a side of the second surface of the first substrate, has a third surface directly opposed to the second surface, and also has a fourth surface opposed to the third surface. The second substrate has a band gap wider than a band gap of the first substrate. The second substrate includes a multiplication section provided for each of the pixels. The multiplication section applies avalanche multiplication to the electric charge generated at the light receiving section. The first electrode is provided at the first surface of the first substrate and is electrically coupled to the light receiving section. The second electrode is provided at the fourth surface of the second substrate and is electrically coupled to the multiplication section.

A distance measurement apparatus according to an embodiment of the present disclosure includes an optical system, a photodetector, and a signal processing circuit that calculates a distance to a measurement target object on the basis of an output signal from the photodetector. The distance measurement apparatus includes, as the photodetector, the photodetector according to the embodiment of the present disclosure described above.

According to the photodetector of the embodiment of the present disclosure and the distance measurement apparatus of the embodiment, the light receiving section is provided at the first substrate having a narrower band gap, and the multiplication section is provided at the second substrate having a band gap wider than that of the first substrate. This configuration makes it possible to reduce occurrence of a dark current at the multiplication section, while improving quantum efficiency at near-infrared (NIR) and short-wave infrared (SWIR) wavelengths.

### BRIEF DESCRIPTION OF THE DRAWINGS

FIG. 1 is a schematic cross-sectional diagram illustrating an example of a configuration of a photodetector according to an embodiment of the present disclosure.

FIG. 2 is a block diagram illustrating an example of an overall schematic configuration of the photodetector illustrated in FIG. 1.

FIG. 3 is an example equivalent circuit diagram of a unit pixel of the photodetector illustrated in FIG. 1.

FIG. 4A is a schematic plan diagram that describes a layout of an anode of the photodetector illustrated in FIG. 1.

FIG. 4B is a schematic plan diagram that describes a configuration of a multiplication section in a unit pixel of the photodetector illustrated in FIG. 1.

FIG. 5 is a schematic cross-sectional diagram that describes an example of routing of an anode electrode of the photodetector illustrated in FIG. 1.

FIG. 6 is a schematic diagram that describes a flow of electric charge in the photodetector illustrated in FIG. 1.

FIG. 7 is a schematic diagram that describes a flow of electric charge in a photodetector according to a comparative example.

FIG. 8 is a schematic cross-sectional diagram illustrating another example of the configuration of the photodetector according to the embodiment of the present disclosure.

FIG. 9 is a schematic cross-sectional diagram illustrating an example of a configuration of a photodetector according to Modification example 1 of the present disclosure.

FIG. 10 is a schematic cross-sectional diagram illustrating an example of a configuration of a photodetector according to Modification example 2 of the present disclosure.

FIG. 11 is a schematic cross-sectional diagram illustrating an example of a configuration of a photodetector according to Modification example 3 of the present disclosure.

FIG. 12 is a schematic cross-sectional diagram illustrating an example of a configuration of a photodetector according to Modification example 4 of the present disclosure.

FIG. 13 is a schematic cross-sectional diagram illustrating another example of the configuration of the photodetector according to Modification example 4 of the present disclosure.

FIG. 14 is a schematic cross-sectional diagram illustrating an example of a configuration of a photodetector according to Modification example 5 of the present disclosure.

FIG. 15 is a schematic cross-sectional diagram illustrating another example of the configuration of the photodetector according to Modification example 5 of the present disclosure.

FIG. 16 is a schematic cross-sectional diagram illustrating another example of the configuration of the photodetector according to Modification example 5 of the present disclosure.

FIG. 17 is a schematic cross-sectional diagram illustrating an example of a configuration of a photodetector according to Modification example 6 of the present disclosure.

FIG. 18 is a schematic cross-sectional diagram illustrating another example of the configuration of the photodetector according to Modification example 6 of the present disclosure.

FIG. 19 is a schematic cross-sectional diagram illustrating another example of the configuration of the photodetector according to Modification example 6 of the present disclosure.

FIG. 20 is a functional block diagram illustrating an example of an electronic apparatus including the photodetector illustrated in FIG. 1 or the like.

FIG. 21 is a block diagram depicting an example of schematic configuration of a vehicle control system.

FIG. 22 is a diagram of assistance in explaining an example of installation positions of an outside-vehicle information detecting section and an imaging section.

### MODES FOR CARRYING OUT THE INVENTION

The following describes embodiments of the present disclosure in detail with reference to the drawings. The following description is a specific example of the present disclosure, and the present disclosure is not limited to the following embodiments. In addition, the present disclosure is not limited to arrangement, dimensions, dimensional ratios, and the like of the components illustrated in the drawings. It is to be noted that description is given in the following order.
1. Embodiment
(A photodetector in which a light receiving section is provided in a Ge substrate, a multiplication section is provided in a Si substrate, and an anode is provided on a light receiving surface side of the Ge substrate)
1-1. Configuration of Photodetector
1-2. Method of Manufacturing Photodetector
1-3. Workings and Effects
2. Modification Examples
2-1. Modification Example 1
(An example in which a p-type contact layer is provided over all of the light receiving surface of the Ge substrate)
2-2. Modification Example 2
(An example in which a SiGe layer is provided between the Ge substrate and the Si substrate)
2-3. Modification Example 3
(An example in which an impurity diffusion region is provided over all of a surface of the Si substrate that is opposed to the Ge substrate)
2-4. Modification Example 4
(An example in which an element separation section is provided between unit pixels adjacent to each other at the Si substrate)
2-5. Modification Example 5
(An example in which an avalanche multiplication region is provided locally in a middle of a unit pixel P)
2-6. Modification Example 6
(An example in which an element separation section is further provided between unit pixels adjacent to each other at the Ge substrate)
3. Application Example
4. Practical Application Example

### 1. EMBODIMENT

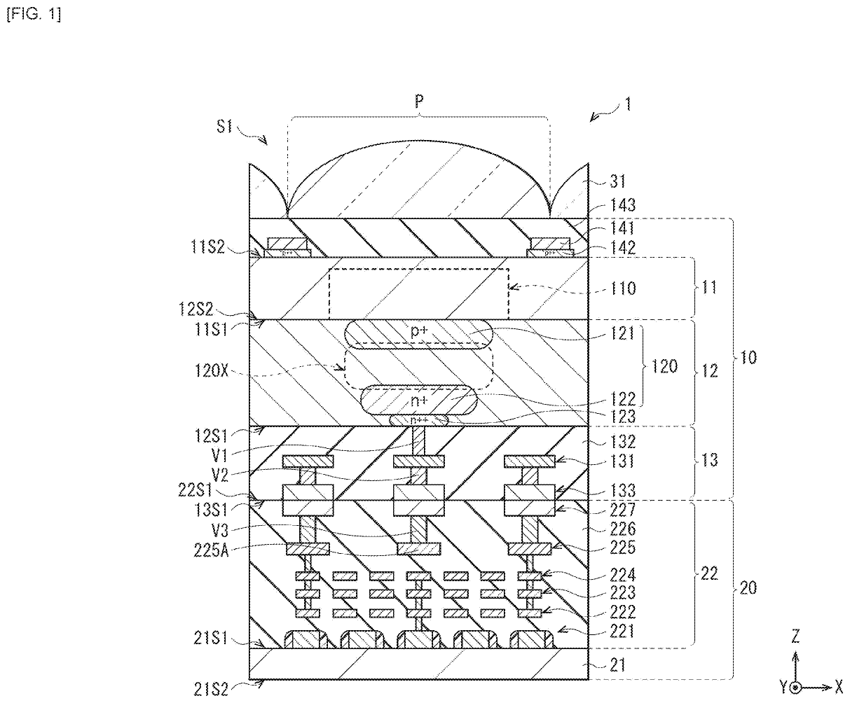

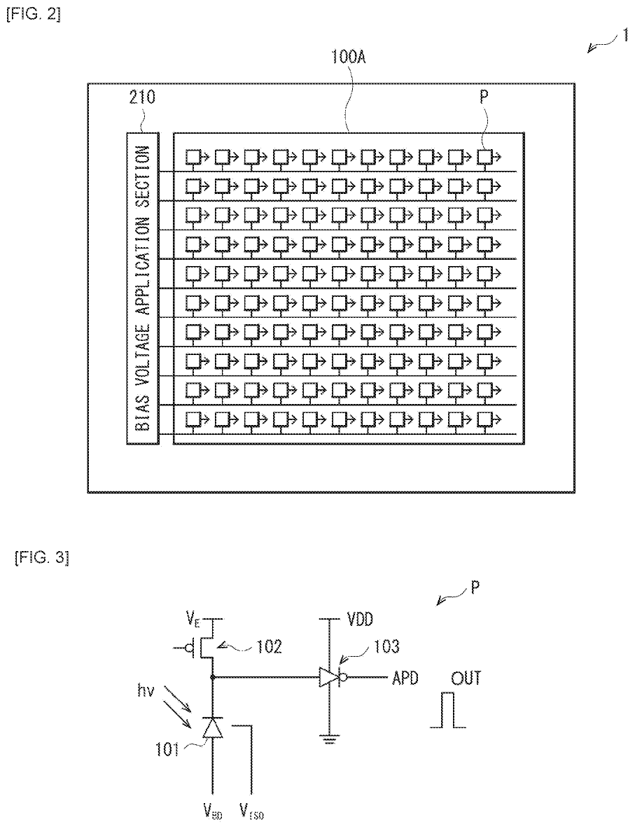

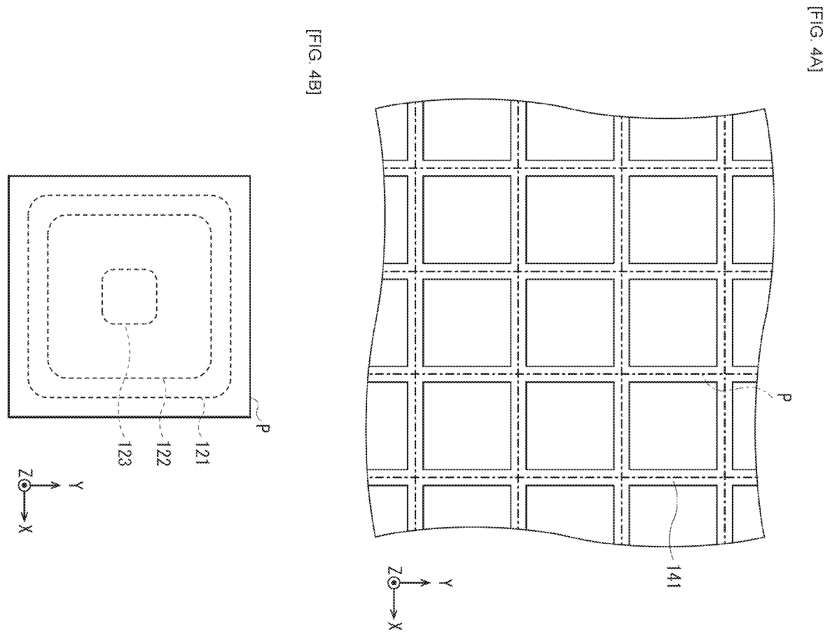

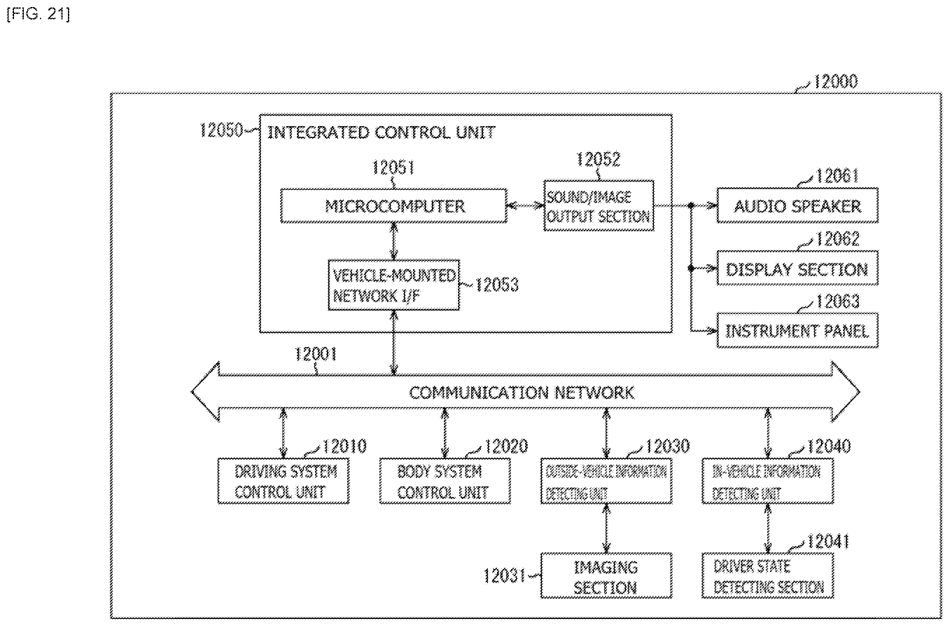

FIG. 1 schematically illustrates an example of a cross-sectional configuration of a photodetector (a photodetector 1) according to an embodiment of the present disclosure. FIG. 2 is a block diagram illustrating a schematic configuration of the photodetector 1 illustrated in FIG. 1. FIG. 3 is a diagram illustrating an example of an equivalent circuit of a unit pixel P of the photodetector 1 illustrated in FIG. 1. The photodetector 1 is applicable to, for example, a distance image sensor (a distance image apparatus 1000 to be described later, see FIG. 20) that performs distance measurement by a ToF (Time-of-Flight) method, an image sensor, or the like.

### 1-1. Configuration of Photodetector

The photodetector 1 includes, for example, a pixel array unit 100A in which a plurality of unit pixels P is disposed in an arrayed manner in a row direction and in a column direction, and also includes a peripheral unit 100B provided around the pixel array unit 100A. For example, a bias voltage application section 210 is provided in the peripheral unit 100B, as illustrated in FIG. 2. The bias voltage application section 210 applies a bias voltage to each of the unit pixels P in the pixel array unit 100A. In the present embodiment, a description will be given of a case where an electron (e) is read out as signal electric charge.

As illustrated in FIG. 3, the unit pixel P includes a light receiving element 101, a quenching resistor 102 including a p-type MOSFET (Metal-Oxide-Semiconductor Field-Effect Transistor), and an inverter 103 including, for example, a complementary-type MOSFET.

The light receiving element 101 converts entering light into an electric signal by photoelectric conversion and outputs the converted light. The light receiving element 101 collaterally converts the entering light (photon) into the electric signal by photoelectric conversion, and outputs a pulse corresponding to the entrance of the photon. The light receiving element 101 is, for example, a SPAD element, and has a characteristic that, for example, an avalanche multiplication region (a depletion layer) 120X is formed by a large positive voltage applied to a cathode, and electrons generated in response to the entrance of one photon cause avalanche multiplication to occur, causing a large current to flow. The light receiving element 101 has, for example, an anode coupled to the bias voltage application section 210 and the cathode coupled to a source terminal of the quenching resistor 102. A device voltage VB (for example, a negative voltage) is applied from a device voltage application section to the anode of the light receiving element 101.

The quenching resistor 102 is coupled in series to the light receiving element 101. The quenching resistor 102 has the source terminal coupled to the cathode of the light receiving element 101 and has a drain terminal coupled to an unillustrated power supply. An excitation voltage V_{E} from the power supply is applied to the drain terminal of the quenching resistor 102. Once the voltage resulting from electrons having been subjected to the avalanche multiplication at the light receiving element 101 reaches a positive voltage V_{BD}, the quenching resistor 102 emits the electrons multiplied at the light receiving element 101 to perform quenching in which the voltage is returned to an initial voltage.

The inverter 103 has an input terminal coupled to the cathode of the light receiving element 101 and to the source terminal of the quenching resistor 102, and also has an output terminal coupled to an unillustrated arithmetic processing unit disposed at a subsequent stage. The inverter 103 outputs a light reception signal on the basis of electric charge (signal electric charge) multiplied at the light receiving element 101. More specifically, the inverter 103 shapes the voltage generated by the electrons multiplied by the light receiving element 101. Thereafter, to the arithmetic processing unit, the inverter 103 outputs a light reception signal (APD OUT) generated with a pulse waveform illustrated in, for example, FIG. 3, with an arrival time of one font as a starting point. For example, the arithmetic processing unit performs arithmetic processing for determining a distance to a subject on the basis of a timing at which the pulse indicating the arrival time of one font is generated in each light reception signal, and determines the distance for each of the unit pixels P. Thereafter, a distance image is generated on the basis of those distances. In the distance image, the distances to the subject detected by the plurality of unit pixels P are two-dimensionally arranged.

The photodetector 1 is, for example, what is called a back-illuminated type photodetector in which a logic substrate 20 is stacked on a front surface side of a sensor substrate 10, and receives light from a back surface side of the sensor substrate 10. The sensor substrate 10 includes a Ge substrate 11 having a pair of surfaces (a first surface 11S1 and a second surface 11S2) that are opposed to each other, and also includes a Si substrate 12 having a pair of surfaces (a third surface 12S1 and a fourth surface 12S2) that are opposed to each other. The Ge substrate 11 is disposed on a light entrance side S1 with the second surface 11S2 as a light receiving surface. The Si substrate 12 is disposed on a side opposite to the light entrance side S1 to allow the fourth surface 12S2 to be directly opposed to the first surface 11S1 of the Ge substrate 11. The photodetector 1 includes the light receiving element 101 for each of the unit pixels P. The light receiving element 101 includes a light receiving section 110 and a multiplication section 120. The light receiving section 110 is provided at the Ge substrate 11. The multiplication section 120 is provided at the Si substrate 12. An anode 141 to be electrically coupled to the light receiving section 110 is provided at the second surface 11S2 of the Ge substrate. A cathode 225A is provided on a third surface 12S1 side of the Si substrate 12.

It is to be noted that symbols “p” and “n” in the drawing represent a p-type semiconductor region and an n-type semiconductor region, respectively. In addition, “+” or “−” at the end of “p” indicates an impurity concentration of the p-type semiconductor region. Similarly, “+” or “−” at the end of “n” indicates an impurity concentration of the n-type semiconductor region. Here, the larger the number of “+”, the higher the impurity concentration, and the larger the number of “−”, the lower the impurity concentration. The same applies to the drawings after this.

The sensor substrate 10 includes, for example, the Ge substrate 11, the Si substrate 12, and a multilayer wiring layer 13. For example, the light receiving section 110 is formed at the Ge substrate 11 for each of the unit pixels P. At the Si substrate 12, a p-type semiconductor region (p⁺) 121 is provided on the third surface 12S1 side, and an n-type semiconductor region (n+) 122 is provided on a fourth surface 12S2 side. These regions are included in the multiplication section 120.

It is to be noted that the substrate where the light receiving section 110 is to be formed may be a substrate including a material other than germanium (Ge), provided that a band gap thereof is narrower than that of the substrate (the Si substrate 12) where the multiplication section 120 is to be formed. For example, a compound semiconductor substrate (e.g., a SiGe substrate) including silicon (Si) and Ge, or a substrate including indium (In)-gallium (Ga)-arsenic (As) may be used.

The light receiving element 101 includes a multiplication region (the avalanche multiplication region) for applying the avalanche multiplication to the electric charge by means of a high electric field region, and is, as described above, the SPAD element that is able to form the avalanche multiplication region (the depletion layer) 120X by application of a large positive voltage to the cathode 225A, and to apply the avalanche multiplication to electrons generated in response to the entrance of one photon.

The light receiving element 101 includes the light receiving section 110 and the multiplication section 120.

The light receiving section 110 corresponds to a specific example of a “light receiving section” according to the present disclosure, and has a photoelectric conversion function of absorbing light that enters from the second surface 11S2 of the Ge substrate 11 and generating electric charge corresponding to the amount of the received light. The electric charge (electrons) generated at the light receiving section 110 is transferred to the multiplication section 120 due to a potential gradient.

The multiplication section 120 corresponds to a specific example of a “multiplication section” according to the present disclosure, and applies avalanche multiplication to electric charge (here, electrons (e)) generated at the light receiving section 110. As described above, the multiplication section 120 includes the p-type semiconductor region (p⁺) 121 and the n-type semiconductor region (n⁺) 122. The p-type semiconductor region (p⁺) 121 is provided at or around an interface of the fourth surface 12S2 of the Si substrate 12. The n-type semiconductor region (n⁺) 122 is formed at or around an interface of the third surface 12S1 of the Si substrate 12.

In the light receiving element 101, the avalanche multiplication region 120X is between the p-type semiconductor region (p⁺) 121 provided at or around the interface of the fourth surface 12S2 of the Si substrate 12 and the n-type semiconductor region (n⁺) 122 provided at or around the interface of the third surface 12S1 of the Si substrate 12. The avalanche multiplication region 120X is a high electric field region (the depletion layer) formed between the p-type semiconductor region (p⁺) 121 and the n-type semiconductor region (n⁺) 122 by a large positive voltage applied to the cathode. In the avalanche multiplication region 120X, the electrons (e⁻) generated by one photon entering the light receiving element 101 are multiplied.

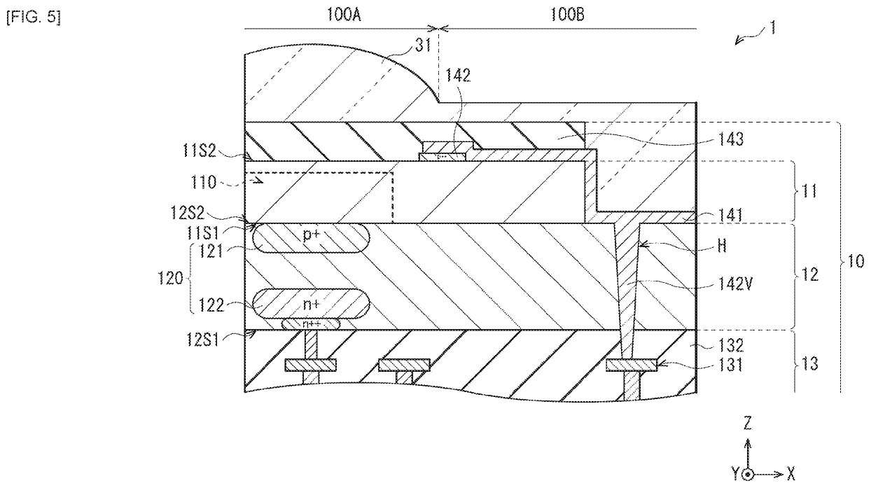

The anode 141 to which the device voltage VB is to be applied is provided at the second surface 11S2 of the Ge substrate 11 with a p-type contact layer (p⁺⁺) 142 being interposed therebetween. FIG. 4A schematically illustrates a planar layout of the anode 141. In the present embodiment, the anode 141 is provided between the plurality of unit pixels P disposed in an arrayed manner, and is provided at the second surface 11S2 of the Ge substrate 11 in a lattice form in plan view. In addition, as illustrated in FIG. 5, the anode 141 extends to the peripheral unit 100B. Specifically, in the peripheral unit 100B, the anode 141 extends from the second surface 11S2 of the Ge substrate 11 to the fourth surface 12S2 of the Si substrate 12 via a side surface. The anode 141 penetrates through between the third surface 12S1 and the fourth surface 12S2 of the Si substrate 12, and is electrically coupled to the bias voltage application section 210 provided at the logic substrate 20 through a through wiring line 142V extending to a wiring layer 131, for example.

The anode 141 includes, for example, aluminum (Al), copper (Cu), tungsten (W), or the like.

An n-type contact region (n⁺⁺) 123 for electrically coupling the cathode 225A and the n-type semiconductor region (n⁺) 122 to each other is further provided at the Si substrate 12. The n-type contact region (n⁺⁺) 123 is so provided within the Si substrate 12 as to face the third surface 12S1 and be in contact with the n-type semiconductor region (n⁺) 122. FIG. 4B schematically illustrates a planar configuration of the multiplication section 120 in the unit pixel P. The p-type semiconductor region (p⁺) 121 and the n-type semiconductor region (n⁺) 122 are each provided substantially in a middle of the unit pixel P and each have a substantially rectangular shape as with the unit pixel P, for example. The n-type semiconductor region (n⁺) 122 is formed to be smaller than the p-type semiconductor region (p+) 121, and the n-type contact region (n⁺⁺) 123 is formed to be further smaller.

The multilayer wiring layer 13 is provided on a side (specifically, the third surface 12S1 side of the Si substrate 12) of the sensor substrate 10 that is opposite to the light entrance side S1. In the multilayer wiring layer 13, the wiring layer 131 including one or more wiring lines is formed within an interlayer insulating layer 132. The wiring layer 131 is used, for example, to supply a voltage to be applied to the light receiving element 101, or to extract electric charge generated at the light receiving element 101. Some of the wiring lines of the wiring layer 131 are electrically coupled to the n-type contact region (n⁺⁺) 123 through a via V1. A plurality of pad electrodes 133 is embedded in a front surface (a front surface 13S1 of the multilayer wiring layer 13) of the interlayer insulating layer 132 that is on a side opposite to a Si substrate 12 side. The plurality of pad electrodes 133 is electrically coupled, through a via V2, to some of the wiling lines of the wiring layer 131. Note that FIG. 1 illustrates an example in which one wiring layer 131 is formed within the multilayer wiring layer 13; however, the total number of wiring layers within the multilayer wiring layer 13 is not limited, and two or more wiring layers may be formed.

The interlayer insulating layer 132 includes, for example, a single-layer film including one of silicon oxide (SiOₓ), TEOS, silicon nitride (SiNₓ), silicon oxynitride (SiOₓN_{y}), and the like, or a stacked film including two or more of these materials.

The wiring layer 131 includes, for example, aluminum (Al), copper (Cu), tungsten (W), or the like.

The pad electrode 133 is exposed at a bonding surface (the front surface 13S1 of the multilayer wiring layer 13) to be bonded to the logic substrate 20, and is used, for example, for coupling to the logic substrate 20. The pad electrode 133 includes, for example, copper (Cu).

The logic substrate 20 includes, for example, a semiconductor substrate 21 including a Si substrate, and a multilayer wiring layer 22. The logic substrate 20 includes a logic circuit which includes, for example, the bias voltage application section 210 described above, a readout circuit that outputs a pixel signal based on electric charge outputted from the unit pixels P of the pixel array unit 100A, a vertical drive circuit, a column signal processing circuit, a horizontal drive circuit, an output circuit, and the like.

In the multilayer wiring layer 22, for example, a gate 221 of a transistor included in the readout circuit and wiring layers 222, 223, 224, and 225 each including one or more wiring lines are stacked in order from a semiconductor substrate 21 side with an interlayer insulating layer 226 being interposed therebetween. A plurality of pad electrodes 227 is embedded in a front surface (a front surface 22S1 of the multilayer wiring layer 22), of the interlayer insulating layer 226, that is on a side opposite to the semiconductor substrate 21 side,. The plurality of pad electrodes 227 is electrically coupled to some of the wiring lines of the wiring layer 225 via a via V3.

As with an interlayer insulating layer 182, the interlayer insulating layer 117 includes, for example, a single-layer film including one of silicon oxide (SiOₓ), TEOS, silicon nitride (SiNₓ), silicon oxynitride (SiOₓN_{y}), and the like, or a stacked film including two or more of these materials.

As with a wiring layer 181, the gate 221 and the wiring layers 222, 223, 224, and 225 each include, for example, aluminum (Al), copper (Cu), tungsten (W), or the like.

The pad electrode 227 is exposed at a bonding surface (the front surface 22S1 of the multilayer wiring layer 22) to be bonded to the sensor substrate 10, and is used, for example, for coupling to the sensor substrate 10. As with the pad electrode 133, the pad electrode 227 includes, for example, copper (Cu).

In the photodetector 1, for example, Cu—Cu bonding is performed between the pad electrode 133 and the pad electrode 227. As a result, the cathode 225A is electrically coupled to the quenching resistor 120 provided on a logic substrate 20 side, and the anode 141 is electrically coupled to the bias voltage application section 210.

A protection layer 143 covering the anode 141 and flattening the light entrance side S1 is provided on a second surface 11S2 side of the Ge substrate 11. A condenser lens 31 is provided on the protection layer 143 for each of the unit pixels P, for example.

The condenser lens 31 is to cause light entering from above to be condensed onto the light receiving section 110, and includes, for example, silicon oxide (SiOₓ) or the like.

### 1-2. Method of Manufacturing Photodetector

It is possible to manufacture the sensor substrate 10 in the following manner, for example. First, the p-type semiconductor region (p⁺) 121 and the n-type semiconductor region (n) 122 are formed on the Si substrate 12 through ion implantation with a p-type or n-type impurity concentration being controlled. Thereafter, the multilayer wiring layer 13 is formed on the third surface 12S1 of the Si substrate 12. Thereafter, the logic substrate 20 having been fabricated separately is bonded. At this time, the plurality of pad electrodes 133 exposed at the bonding surface (the front surface 13S1) of the multilayer wiring layer 13 and the plurality of pad sections 217 exposed at the bonding surface (the front surface 22S) of the multilayer wiring layer 22 on the logic substrate 20 side are subjected to Cu—Cu bonding.

Thereafter, the fourth surface 12S2 of the Si substrate 12 is polished by, for example, CMP to reduce a thickness thereof. Thereafter, for example, the Ge substrate 11 is formed on the fourth surface 12S2 of the Si substrate 12 by an epitaxial crystal growth method such as a metal organic chemical vapor deposition (Metal Organic Chemical Vapor Deposition: MOCVD) method, for example.

Thereafter, the second surface 11S2 of the Ge substrate 11 is polished by, for example, CMP, following which a resist film is patterned on the second surface 11S2 of the Ge substrate 11, and the p-type contact layer (p⁺⁺) 142 is formed on the second surface 11S2 exposed from the resist film, by an epitaxial crystal growth method such as an MOCVD method. Thereafter, the resist film is removed, following which a metal film including, for example, tungsten (W), copper (Cu), an aluminum (Al) film, or the like is formed by a CVD (Chemical Vapor Deposition) method, a PVD (Physical Vapor Deposition) method, an ALD (Atomic Layer Deposition) method, a vapor deposition method, or the like. Thereafter, the metal film is patterned by a photolithography technique and etching to thereby form the anode 141. Thereafter, the protection layer 143 and the condenser lens 31 are sequentially formed. The photodetector 1 illustrated in FIG. 1 is thus completed.

### 1-3. Workings and Effects

In the photodetector 1 according to the present embodiment, the light receiving section 110 is provided at the Ge substrate 11 having a narrow band gap, and the multiplication section 120 is provided at the Si substrate 12 having a band gap wider than that of the Ge substrate 11. This makes it possible to reduce the occurrence of a dark current at the multiplication section 120 while improving the quantum efficiency at NIR and SWIR. This will be described below.

Improvement in sensitivity is demanded of a photodetector that detects NIR, SWIR, or the like. Methods for achieving this include a technique that uses Ge for a multiplication pixel. Ge is narrow in band gap relative to Si, and high in quantum efficiency at NIR and SWIR wavelengths. Thus, a photodetector using Ge for a photoelectric conversion element has been developed as described above. In a case of using this technique, the photoelectric conversion region and the multiplication region are all formed within Ge. However, as Ge has a narrow band gap, a dark current frequently occurs accordingly, which causes deterioration in terms of noise.

In contrast, according to the present embodiment, the light receiving section 110 is provided at the Ge substrate 11 having a narrow band gap to thereby improve the quantum efficiency at NIR and SWIR, and the multiplication section 120 is provided at the Si substrate 12 having a band gap wider than that of the Ge substrate 11 to thereby reduce the occurrence of a dark current.

Thus, the photodetector 1 according to the present embodiment makes it possible to reduce the occurrence of noise while improving the sensitivity at NIR and SWIR wavelengths.

In addition, in the photodetector 1 according to the present embodiment, the anode 141 is provided between adjacent unit pixels P at the second surface 11S2 of the Ge substrate 11 that serves as the light receiving surface.

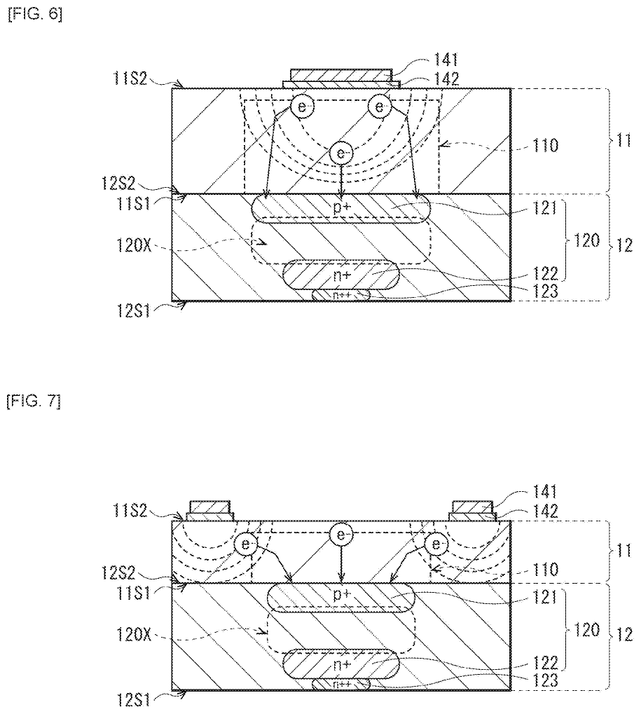

A strong electric field formed within the avalanche multiplication region 120X is not uniform, and accordingly, the probability (sensitivity) of multiplication can vary depending on a position through which electric charge having been photoelectrically converted at the light receiving section 110 passes. FIG. 6 schematically illustrates a flow of electric charge in a case where the anode 141 is provided in the middle of the unit pixel P of the second surface 11S2 of the Ge substrate 11. In the case where the anode 141 is provided in the middle of the unit pixel P, the electric charge having been photoelectrically converted at the light receiving section 110 is transferred to the multiplication section 120 while spreading outward from the middle of the unit pixel P. Thus, the electric charge transferred to the multiplication section 120 travels across the whole of the avalanche multiplication region 120X, which leads to variations in the probability of multiplication.

In contrast, in a case where the anode 141 is provided between adjacent unit pixels P at the second surface 11S2 of the Ge substrate 11 as in the present embodiment, a potential at a peripheral edge part of the unit pixel P is drawn toward the negative side, and the electric charge having been photoelectrically converted at the light receiving section 110 is transferred to the multiplication section 120 while moving toward a middle part of the unit pixel P as illustrated in FIG. 7. Thus, the electric charge transferred to the multiplication section 120 concentratedly passes through the middle of the avalanche multiplication region 120X, which makes the probability of multiplication uniform.

In addition, in a case where the p-type semiconductor region (p⁺) that constitutes the multiplication section 120 is formed at the interface of the fourth surface 12S2 on the light entrance side S1, a transfer barrier can be formed on an electric charge transfer path from the light receiving section 110. In the present embodiment, however, a negative voltage is applied to the anode 141, for example. This increases a potential difference from a cathode 225A side and thus promotes transfer of electric charge within the multiplication section 120.

Accordingly, it is possible to further improve the sensitivity at NIR and SWIR wavelengths.

Furthermore, in the present embodiment, the condenser lens 31 is provided on the light entrance side S1 for each of the unit pixels P, for example. This makes it possible to reduce vignetting of irradiation light due to the anode 141, thus making it possible to further improve the sensitivity at NIR and SWIR wavelengths.

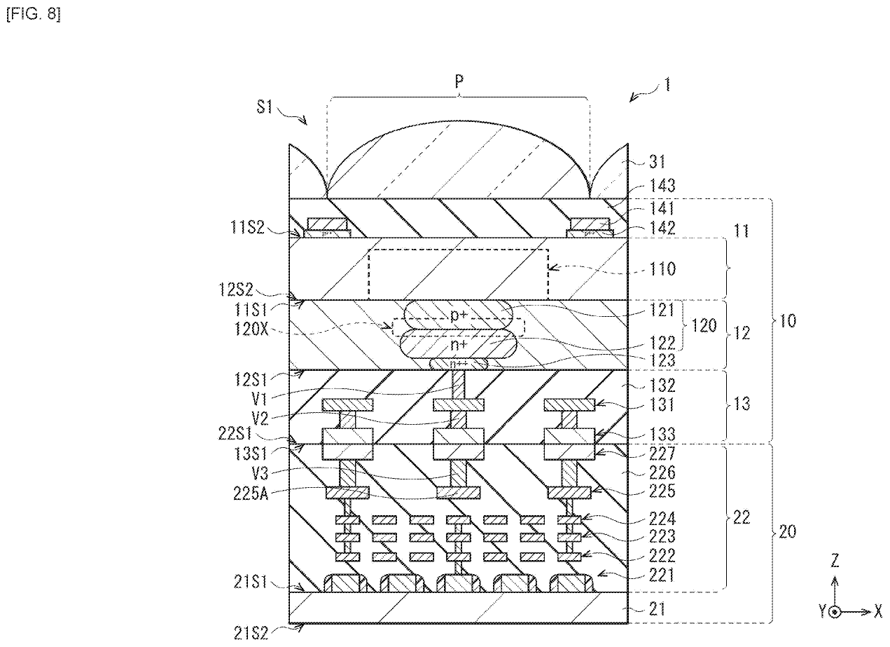

It is to be noted that FIG. 1 or the like illustrates an example in which a region that does not contain any impurity is provided between the p-type semiconductor region (p⁺) 121 and the n-type semiconductor region (n⁺) 122 that are included in the multiplication section 120; however, this is not limitative. The p-type semiconductor region (p⁺) 121 and the n-type semiconductor region (n⁺) 122 that are included in the multiplication section 120 may be in contact with each other within the Si substrate 12, as illustrated in FIG. 8, for example. This makes it possible to improve a timing jitter characteristic. Further, it is possible to reduce the thickness of the Si substrate 12 in a Z axis direction to thereby achieve reduction in profile.

Next, Modification examples 1 to 6 according to the present disclosure, an application example, and a practical application example will be described. In the following, components similar to those of the embodiment described above are denoted with the same reference numerals, and descriptions thereof are omitted as appropriate.

### 2. MODIFICATION EXAMPLES

### 2-1. Modification Example 1

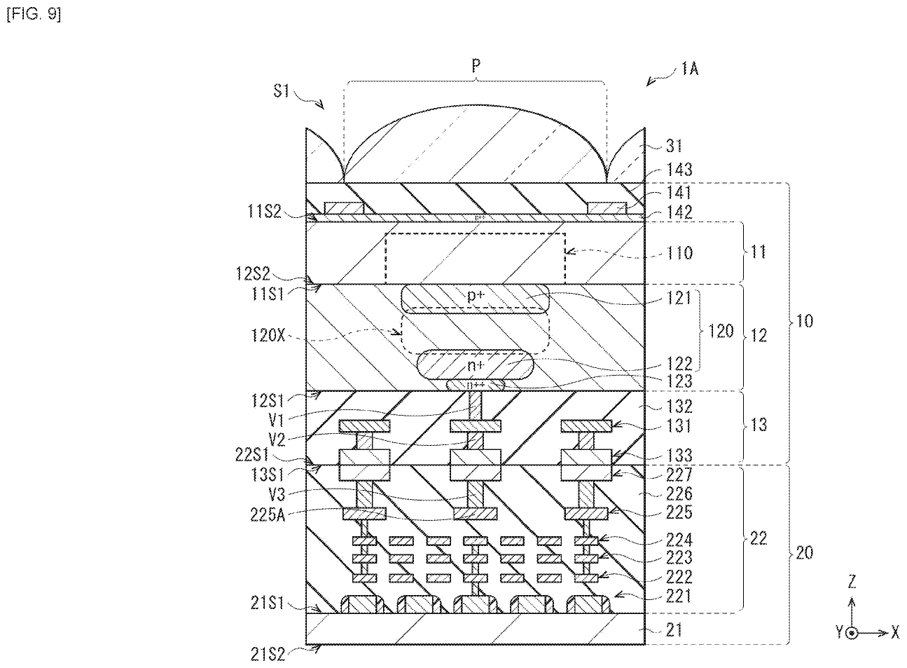

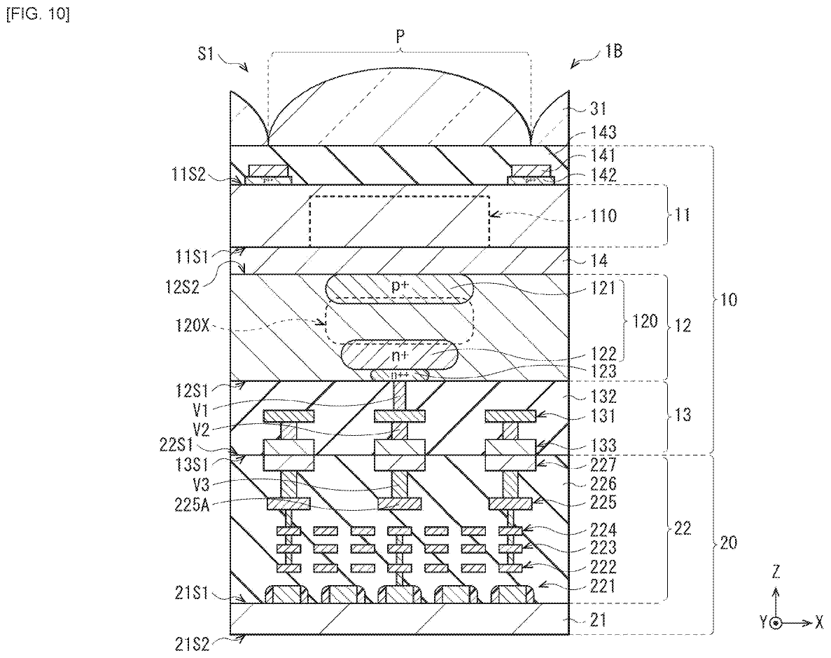

FIG. 9 schematically illustrates an example of a cross-sectional configuration of a photodetector (a photodetector 1A) according to Modification example 1 of the present disclosure. The photodetector 1A is applicable to a distance image sensor (the distance image apparatus 1000) that performs distance measurement by the ToF (Time-of-Flight) method, an image sensor, or the like, as in the embodiment described above. The photodetector 1A according to the present modification example differs from the embodiment described above in that the p-type contact layer (p⁺⁺) 142 is formed over all of the second surface 11S2 of the Ge substrate 11.

As described above, in the photodetector 1A according to the present modification example, the p-type contact layer (p⁺⁺) 142 is formed over all of the second surface 11S2 of the Ge substrate 11. This makes it possible to form an electric field gradient not only at or around the anode 141 but also in the middle part of the unit pixel P, which promotes transfer of electric charge within the light receiving section 110. In addition, a vicinity of an interface of the second surface 11S2 of the Ge substrate 11 is filled with a high concentration of holes. This makes it possible to suppress the occurrence of a dark current at the interface of the second surface 11S2.

### 2-2. Modification Example 2

FIG. 10 schematically illustrates an example of a cross-sectional configuration of a photodetector (a photodetector 1B) according to Modification example 2 of the present disclosure. The photodetector 1B is applicable to a distance image sensor (the distance image apparatus 1000) that performs distance measurement by the ToF (Time-of-Flight) method, an image sensor, or the like, as in the embodiment described above. The photodetector 1B according to the present modification example differs from the embodiment described above in that a SiGe layer 14 having a band gap that falls between the band gap of the substrate 11 and the band gap of the substrate 12 is disposed between the Ge substrate 11 and the Si substrate 12.

As described above, in the photodetector 1B according to the present modification example, the SiGe layer 14 that corresponds to a specific example of a “semiconductor layer” according to the present disclosure is disposed between the Ge substrate 11 and the Si substrate 12. This makes it possible to suppress the occurrence of an interface state resulting from lattice mismatch at an interface between the Ge substrate 11 and the Si substrate 12. Thus, it is possible to reduce the occurrence of a dark current at the interface between the Ge substrate 11 and the Si substrate 12.

### 2-3. Modification Example 3

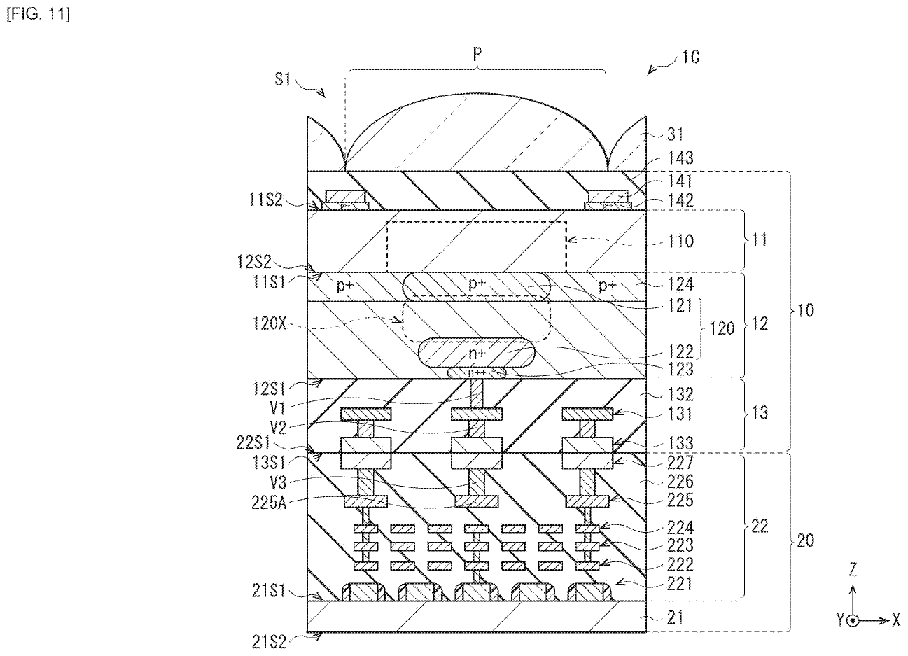

FIG. 11 schematically illustrates an example of a cross-sectional configuration of a photodetector (a photodetector 1C) according to Modification example 3 of the present disclosure. The photodetector 1C is applicable to a distance image sensor (the distance image apparatus 1000) that performs distance measurement by the ToF (Time-of-Flight) method, an image sensor, or the like, as in the embodiment described above. The photodetector 1C according to the present modification example differs from the embodiment described above in that a p-type semiconductor region (p⁺) 124 is provided over all of the fourth surface 12S2 of the Si substrate 12 where the p-type semiconductor region (p⁺) 121 is formed.

As described above, in the photodetector 1C according to the present modification example, the p-type semiconductor regions (p⁺) 121 and 124 are provided over all of the fourth surface 12S2 of the Si substrate 12. This makes it possible to fill the vicinity of the interface of the second surface 11S2 of the Ge substrate 11 with the high concentration of holes. This makes it possible to reduce the occurrence of a dark current resulting from lattice mismatch at the interface between the Ge substrate 11 and the Si substrate 12.

It is to be noted that although the impurity concentration of the p-type semiconductor regions (p⁺) 121 and 124 formed over all of the fourth surface 12S2 of the Si substrate 12 may be uniform, it is preferable that the impurity concentration of the p-type semiconductor region (p⁺) 124 be relatively lower than that of the p-type semiconductor region (p⁺) 121 provided for each of the unit pixels P. This makes it possible to form a strong electric field selectively in the middle of the unit pixel P.

### 2-4. Modification Example 4

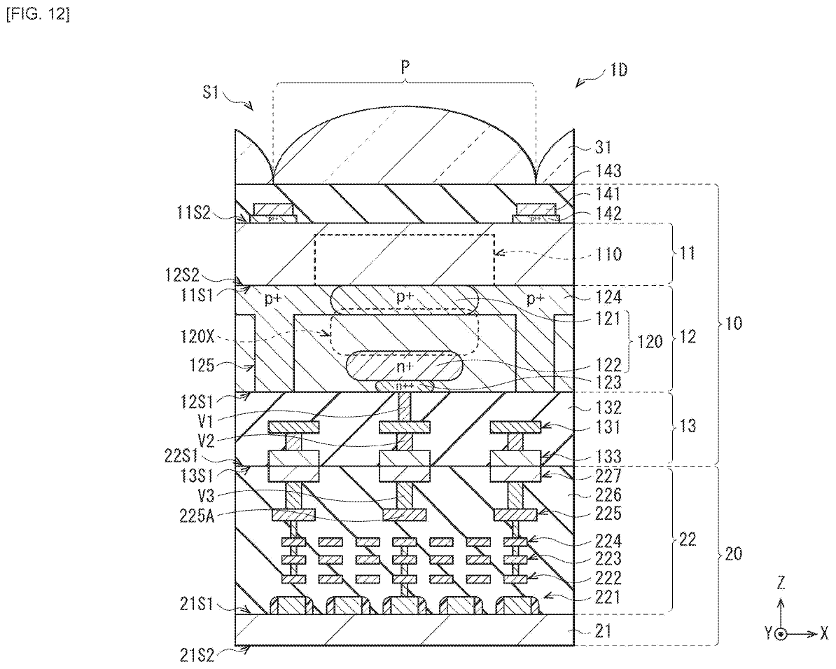

FIG. 12 schematically illustrates an example of a cross-sectional configuration of a photodetector (a photodetector 1D) according to Modification example 4 of the present disclosure. The photodetector 1D is applicable to a distance image sensor (the distance image apparatus 1000) that performs distance measurement by the ToF (Time-of-Flight) method, an image sensor, or the like, as in the embodiment described above. The photodetector 1D according to the present modification example differs from Modification example 3 described above in that an element separation section 125 is provided between adjacent unit pixels P at the Si substrate 12 where the multiplication section 120 is formed.

The element separation section 125 electrically separates adjacent unit pixels P from each other, and corresponds to a specific example of a “separation section” according to the present disclosure. It is possible to form the element separation section 125 by, for example, causing the p-type semiconductor region (p⁺) 124 provided between adjacent p-type semiconductor regions (p⁺) 121 in Modification example 3 described above to extend, between adjacent unit pixels P, toward the third surface 12S1.

As described above, in the present modification example, the element separation section 125 is provided between adjacent unit pixels P at the Si substrate 12 where the multiplication section 120 is formed. This makes it possible to reduce the occurrence of color mixture due to leakage of electric charge between adjacent unit pixels P.

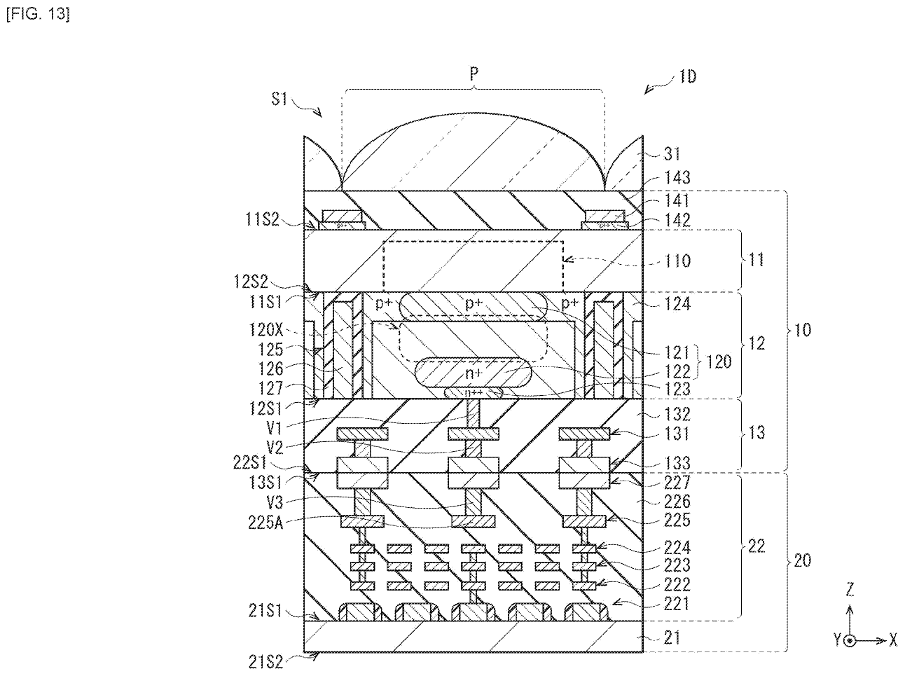

In addition, the element separation section 125 may be formed by, as illustrated in FIG. 13, for example, forming a light-blocking film 126 in an embedded manner in the p-type semiconductor region (p⁺) 124 extending from the fourth surface 12S2 toward the third surface 12S1 of the Si substrate 12, with an insulating film 127 being interposed therebetween. The light-blocking film 126 includes, for example, an electrically-conductive material having a light-blocking property. Examples of such a material may include tungsten (W), silver (Ag), copper (Cu), aluminum (Al), an alloy of Al and copper (Cu), and the like. The insulating film 127 includes, for example, a silicon oxide (SiOₓ) film or the like.

This makes it possible to electrically and optically separate adjacent unit pixels P from each other, thus making it possible to prevent the occurrence of color mixture due to leakage of a self-illuminating component at the avalanche multiplication region 120X into an adjacent one of the unit pixels P.

Furthermore, the light-blocking film 126 may be adapted to be subjected to a voltage independently. For example, applying a negative voltage to the light-blocking film 126 allows a vicinity of an interface of the element separation section 125 to be filled with holes, which makes it possible to reduce the occurrence of a dark current at the interface of the element separation section 125.

### 2-5. Modification Example 5

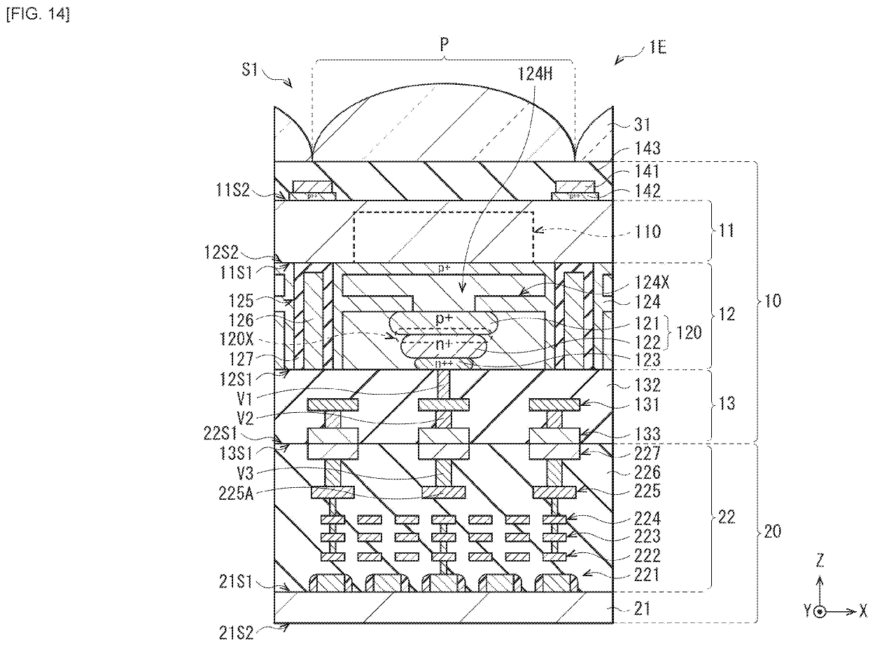

FIG. 14 schematically illustrates an example of a cross-sectional configuration of a photodetector (a photodetector 1E) according to Modification example 5 of the present disclosure. The photodetector 1E is applicable to a distance image sensor (the distance image apparatus 1000) that performs distance measurement by the ToF (Time-of-Flight) method, an image sensor, or the like, as in the embodiment described above. The photodetector 1E according to the present modification example differs from Modification example 4 described above in that an extended section 124X extending within the Si substrate 12 toward the middle of the unit pixel P and having an opening 124H in the middle part of the unit pixel P is provided at the p-type semiconductor region (p⁺) 124 extending at the side surface of the element separation section 125, and that the p-type semiconductor region (p⁺) 121 is locally provided in contact with the extended section 124X on the third surface 12S1 side.

As described above, in the photodetector 1E according to the present modification example, the p-type semiconductor region (p⁺) 121 is spaced apart from the interface of the fourth surface 12S2 of the Si substrate 12, and is locally provided to be in contact with the n-type semiconductor region (n⁺) 122 provided at or around the interface of the third surface 12S1 of the Si substrate 12, for example. This makes it possible to prevent a dark current occurring at the interface between the Ge substrate 11 and the Si substrate 12 or at the interface of the element separation section 125 from being multiplied at the avalanche multiplication region 120X.

In addition, in the present modification example, the p-type semiconductor region (p⁺) 121 is provided closer to the third surface 12S1 of the Si substrate 12. This makes it possible for light that has not been completely absorbed by the light receiving section 110 of the Ge substrate 11 to be absorbed at a portion of the Si substrate 12 above the p-type semiconductor region (p⁺) 121. Accordingly, it is possible to improve efficiency of photoelectric conversion as compared with the above-described embodiment and the like, and it is thus possible to further improve sensitivity.

It is to be noted that the photodetector 1E according to the present modification example may also be configured in the following manner.

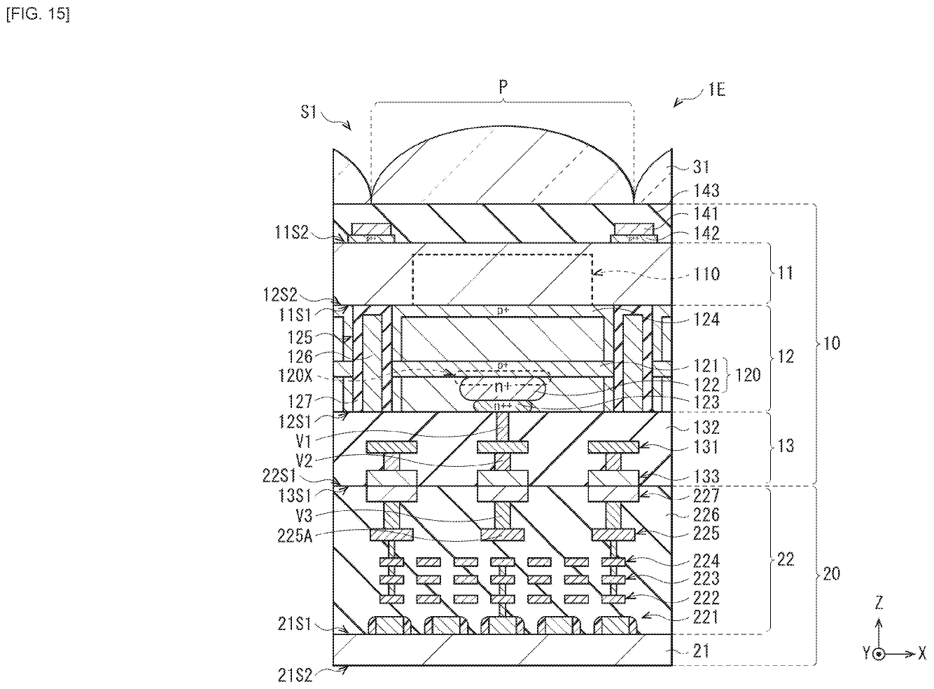

For example, in the photodetector 1E, as illustrated in FIG. 15, for example, the p-type semiconductor region (p⁺) 121 may be formed instead of the extended section 124X over an entire surface of the unit pixel P and may be brought into contact with the p-type semiconductor region (p⁺) 124 extending at the side surface of the element separation section 125. This makes it possible to suppress variations in sensitivity resulting from variations in overlapping of p-type impurities between the extended section 124X and the p-type semiconductor region (p⁺) 121.

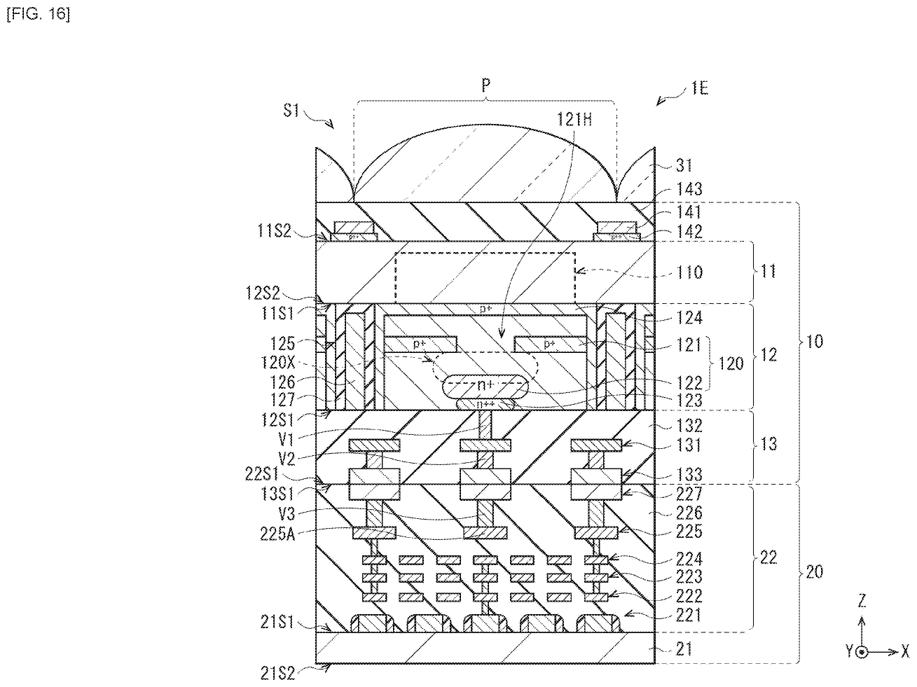

For example, in the photodetector 1E, the extended section 124X may be replaced with the p-type semiconductor region (p⁺) 121, as illustrated in FIG. 16. Specifically, the p-type semiconductor region (p⁺) 121 may be formed within the Si substrate 12 over the entire surface of the unit pixel P so as to be spaced apart from the n-type semiconductor region (n⁺) 122, for example, and may be provided with an opening 121H located substantially in a middle part thereof. In the photodetector 1E illustrated in FIG. 16, a strong electric field due to a fringe electric field is formed between the p-type semiconductor region (p⁺) 121 and the n-type semiconductor region (n⁺) 122. This makes it possible to reduce a possibility that the transfer of electric charge to the multiplication section 120 is blocked due to occurrence of a potential barrier, as compared with a case where the p-type semiconductor region (p⁺) 121 is provided in the middle of the unit pixel P as illustrated in FIG. 14 or FIG. 15, for example.

### 2-6. Modification Example 6

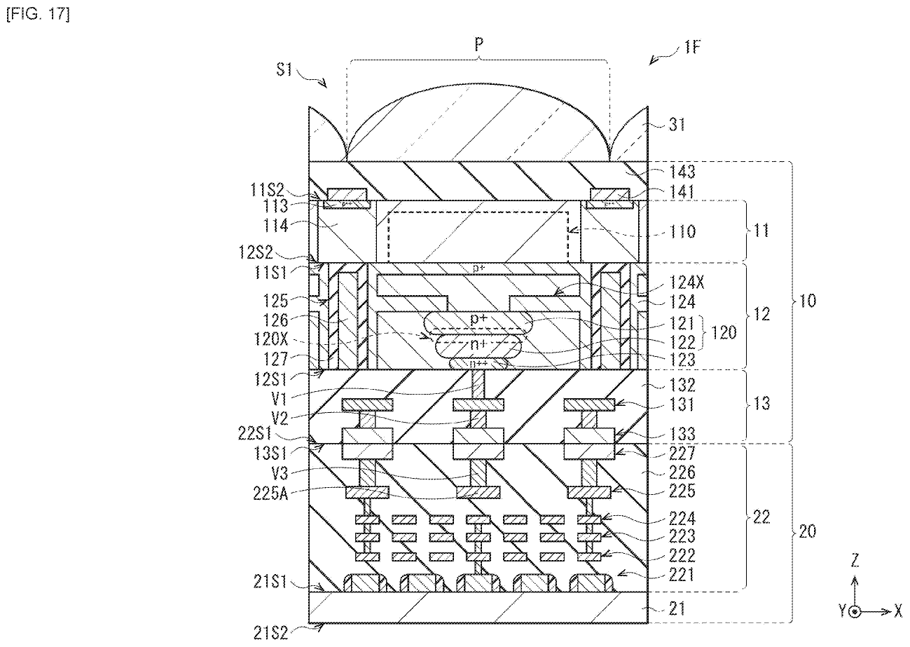

FIG. 17 schematically illustrates an example of a cross-sectional configuration of a photodetector (a photodetector 1F) according to Modification example 6 of the present disclosure. The photodetector 1F is applicable to a distance image sensor (the distance image apparatus 1000) that performs distance measurement by the ToF (Time-of-Flight) method, an image sensor, or the like, as in the embodiment described above. The photodetector 1F according to the present modification example differs from Modification example 5 described above in that a p-type impurity diffusion region (p⁺⁺) 113 is provided instead of the p-type contact layer (p⁺⁺) 142 at the second surface 11S2 of the Ge substrate 11 where the light receiving section 110 is formed, and that a p-type semiconductor region (p⁺) 114 penetrating through between the first surface 11S1 and the second surface 11S2 of the Ge substrate 11, for example, is provided around the p-type impurity diffusion region (p⁺⁺) 113.

As described above, in the present modification example, the p-type impurity diffusion region (p⁺⁺) 113, instead of the p-type contact layer (p⁺⁺) 142, is formed in an embedded manner at the interface of the second surface 11S2 of the Ge substrate 11, and the anode 141 is provided directly on the second surface 11S2 of the Ge substrate 11. This makes the position of the anode 141 relatively close to the light receiving section 110, thus making it possible to reduce the occurrence of color mixture due to leakage of electric charge at adjacent unit pixels P in the light receiving section 110.

In addition, in the present modification example, the p-type semiconductor region (p⁺) 114 penetrating through between the first surface 11S1 and the second surface 11S2 of the Ge substrate 11 is provided around the p-type impurity diffusion region (p⁺⁺) 113. This makes it possible to reduce the occurrence of color mixture due to leakage of electric charge at adjacent unit pixels P in the light receiving section 110.

Furthermore, on a first surface 11S1 side of the Ge substrate 11, the p-type semiconductor region (p⁺) 114 provided around the p-type impurity diffusion region (p⁺⁺) 113 is preferably in contact with the p-type semiconductor region (p⁺) 124 provided at the Si substrate 12, as illustrated in FIG. 17. This makes it possible to efficiently transmit a voltage applied to the anode 141 to the avalanche multiplication region 120X.

It is to be noted that the photodetector 1F according to the present modification example may be configured in the following manner.

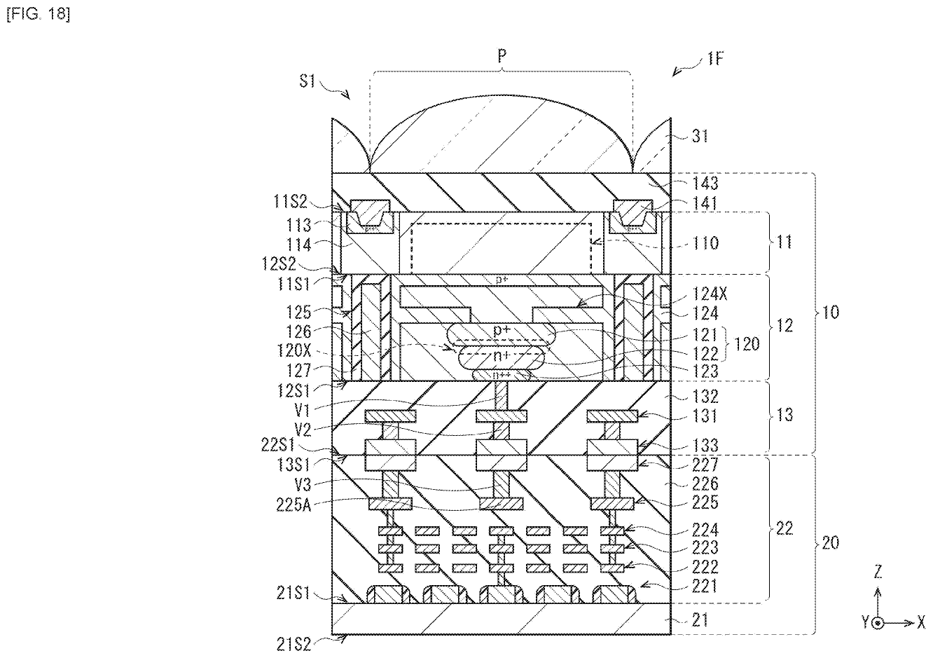

For example, in the photodetector 1F, as illustrated in FIG. 18, a portion of the anode 141 may be embedded in the Ge substrate 11. This makes it possible to reduce the occurrence of color mixture due to leakage of electric charge at adjacent unit pixels P in the light receiving section 110.

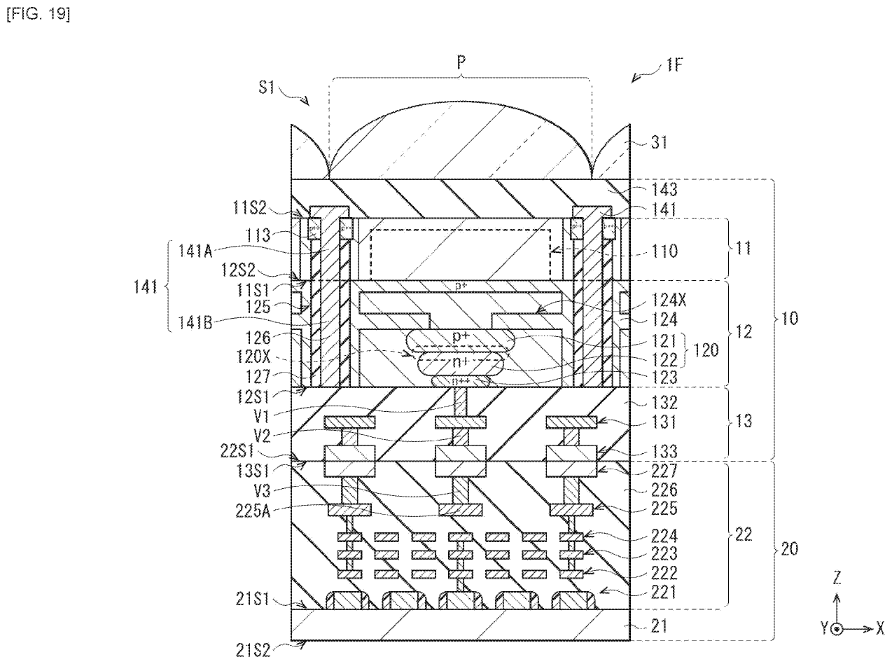

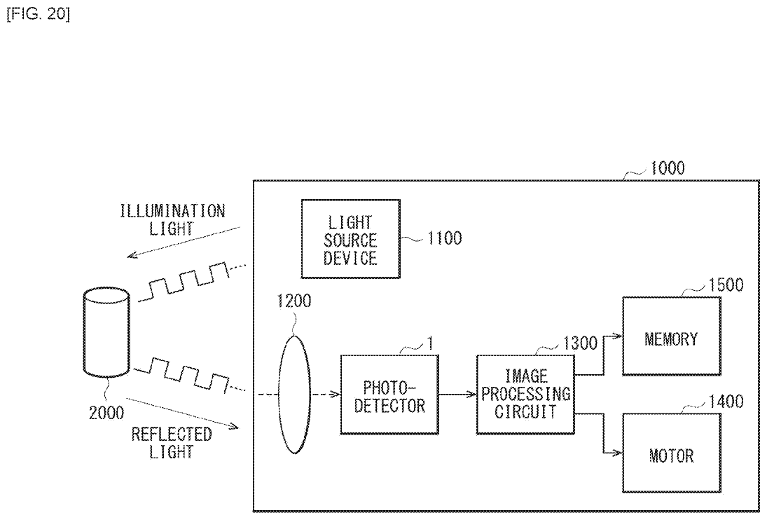

For example, in the photodetector 1F, as illustrated in FIG. 19, a portion of the anode 141 may penetrate through the Ge substrate 11 and the Si substrate 12. This makes it possible to electrically and optically separate adjacent unit pixels P from each other at both the light receiving section 110 and the multiplication section 120, thus making it possible to further prevent the occurrence of color mixture.

In addition, with the photodetector 1F illustrated in FIG. 19, it is possible to couple the anode 141 and the bias voltage application section 210 to each other in the pixel array unit 100A without routing the anode 141 to the peripheral unit 100B.

It is to be noted that although FIG. 19 illustrates an example in which anodes 141A and 141B penetrating through the Ge substrate 11 and the Si substrate 12 are formed to have the same line width, this is not limitative. The anodes 141A and 141B penetrating through the Ge substrate 11 and the Si substrate 12 may be provided with different line widths by, for example, being formed in separate steps.

### 3. Application Example

FIG. 20 illustrates an example of a schematic configuration of the distance image apparatus 1000 serving as an electronic apparatus including the photodetector (for example, the photodetector 1) according to the embodiment and Modification examples 1 to 6 described above. The distance image apparatus 1000 corresponds to a specific example of a “distance measurement apparatus” according to the present disclosure.

The distance image apparatus 1000 includes, for example, a light source device 1100, an optical system 1200, the photodetector 1, an image processing circuit 1300, a monitor 1400, and a memory 1500.

The distance image apparatus 1000 receives light (modulated light or pulsed light) projected from the light source device 1100 toward an irradiation target object 2000 and reflected by a front surface of the irradiation target object 2000, thereby obtaining a distance image corresponding to a distance to the irradiation target object 2000.

The optical system 1200 includes one or a plurality of lenses, and guides image light (entering light) from the irradiation target object 2000 to the photodetector 1 to form an image on a light receiving surface (a sensor unit) of the photodetector 1.

The image processing circuit 1300 performs image processing for constructing the distance image on the basis of a distance signal supplied from the photodetector 1, and the distance image (image data) obtained by the image processing is supplied to the monitor 1400 and displayed thereby, or is supplied to the memory 1500 and stored (recorded) therein.

In the distance image apparatus 1000 configured as described above, application of the above-described photodetector (for example, the photodetector 1) makes it possible to calculate the distance to the irradiation target object 2000 only on the basis of the light reception signal from the highly stable unit pixel P, and to thereby generate a highly accurate distance image. That is, the distance image apparatus 1000 makes it possible to acquire a more accurate distance image.

### 4. Practical Application Example

### (Example of Practical Application to Mobile Body)

The technology according to the present disclosure is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

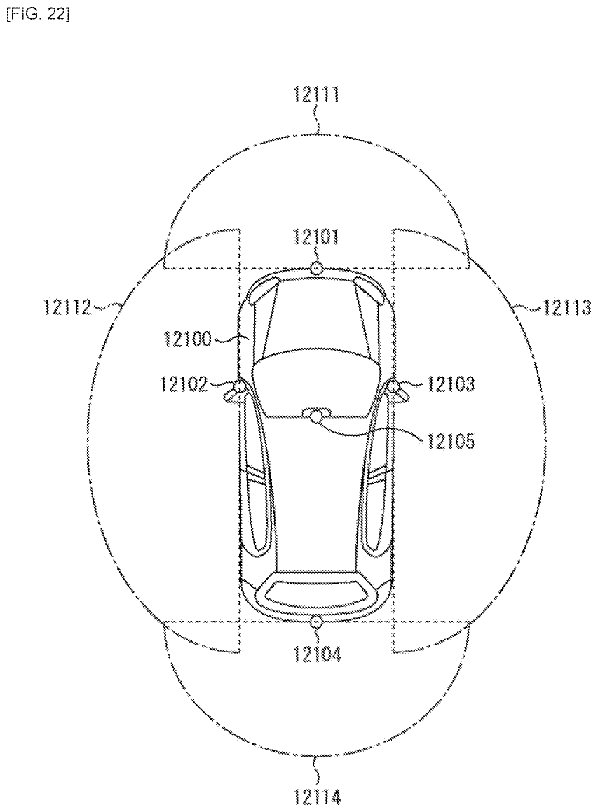

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although the description has been given with reference to the embodiment, Modification examples 1 to 6, the application examples, and the practical application examples, the contents of the present disclosure are not limited to the above-described embodiments and the like, and various modifications are possible. For example, the photodetector of the present disclosure does not have to include all of the components described in the above embodiment and the like, and may include other layers. For example, in a case where the photodetector 1 is to detect light other than visible light (for example, near-infrared light (IR)), the color filter 32 may be omitted.

Further, a polarity of any of the semiconductor regions included in the photodetector according to the present disclosure may be inverted. In addition, in the photodetector according to the present disclosure, holes may serve as the signal charges.

Still further, as long as the photodetector according to the present disclosure is in a state in which the avalanche multiplication occurs by applying a reverse-bias between the anode and the cathode, the respective potentials are not limited.

In addition, in the embodiment and the like described above, the present technology has been described with reference to, by way of example, a stacked-type photodetector in which the sensor substrate 10 and the logic substrate 20 are stacked: however, this is not limitative. For example, the present technology makes it possible to obtain similar effects even in a case of a photodetector in which the logic circuit including the bias voltage application section 210, the readout circuit, the vertical drive circuit, the column signal processing circuit, the horizontal drive circuit, the output circuit, and the like that are provided at the logic substrate 20 in the foregoing embodiment and the like is provided in the peripheral unit 100B.

It is to be noted that the effects described in the foregoing embodiment and the like are merely examples, and may be other effects or may further include other effects.

It is to be noted that the present disclosure may have the following configurations. According to the present technology having the following configurations, the light receiving section is provided at the first substrate having a narrow band gap, and the multiplication section is provided at the second substrate having a band gap wider than that of the first substrate. This makes it possible to reduce the occurrence of a dark current at the multiplication section while improving the quantum efficiency at near-infrared (NIR) and short-wave infrared (SWIR) wavelengths. Accordingly, it is possible to reduce the occurrence of noise while improving the sensitivity at near-infrared and short-wave infrared wavelengths.
(1)

A photodetector including:

a first substrate having a first surface serving as a light receiving surface and a second surface opposed to the first surface, the first substrate having a plurality of pixels disposed in an arrayed manner, the first substrate including a light receiving section provided for each of the pixels, the light receiving section generating, through photoelectric conversion, electric charge corresponding to an amount of received light;

a second substrate disposed on a side of the second surface of the first substrate, the second substrate having a third surface directly opposed to the second surface and also having a fourth surface opposed to the third surface, the second substrate having a band gap wider than a band gap of the first substrate, the second substrate including a multiplication section provided for each of the pixels, the multiplication section applying avalanche multiplication to the electric charge generated at the light receiving section;

a first electrode provided at the first surface of the first substrate and electrically coupled to the light receiving section; and

a second electrode provided at the fourth surface of the second substrate and electrically coupled to the multiplication section.
(2)

The photodetector according to (1) described above, in which the first electrode is provided between the plurality of pixels, and is provided at the first surface of the first substrate in a lattice form.
(3)

The photodetector according to (1) or (2) described above, in which a negative voltage is applied to the first electrode.
(4)

The photodetector according to any one of (1) to (3) described above, further including an impurity diffusion layer that is provided at the first surface of the first substrate and contains a first conduction-type impurity, in which

the first electrode is provided at the first surface of the first substrate with the impurity diffusion layer being interposed between the first electrode and the first surface.
(5)

The photodetector according to (4) described above, in which the impurity diffusion layer is provided over all of the first surface.
(6)

The photodetector according to any one of (1) to (5) described above, in which a semiconductor layer having a band gap that falls between the band gap of the first substrate and the band gap of the second substrate is further provided between the first substrate and the second substrate.
(7)

The photodetector according to any one of (1) to (6) described above, in which the multiplication section includes a first conduction-type region provided on a side of the third surface, and a second conduction-type region provided on a side of the fourth surface.
(8)

The photodetector according to (7) described above, in which the multiplication section further includes a first first-conduction type layer provided at or around an interface of the third surface and having an impurity concentration relatively lower than that of the first conduction-type region.
(9)

The photodetector according to (8) described above, in which

the second substrate further includes a separation section that electrically separates adjacent ones of the pixels from each other, and
the separation section is formed by the first first-conduction type layer extending, between the adjacent ones of the pixels, from the third surface toward the fourth surface.
(10)

The photodetector according to any one of (1) to (9) described above, in which

the second substrate further includes a separation section that electrically separates adjacent ones of the pixels from each other, and

the separation section includes a material having a light-blocking property.
(11)

The photodetector according to (9) or (10) described above, in which

the first first-conduction type layer further includes an extended section extending within the second substrate toward a middle of the pixel, the extended section having a first opening in the middle of the pixel, and

the first conduction-type region is in contact with the extended section on the side of the fourth surface.
(12)

The photodetector according to (9) or (10) described above, in which the first conduction-type region is formed, within the second substrate, over an entire surface of the pixel so as to be in contact with the first first-conduction type layer extending from the third surface toward the fourth surface.
(13)

The photodetector according to (12) described above, in which the first conduction-type region has a second opening in a middle of the pixel.
(14)

The photodetector according to any one of (8) to (13) described above, further including:

an impurity diffusion region formed at the first surface of the first substrate in an embedded manner and containing a first conduction-type impurity; and

a second first-conduction type region provided around the impurity diffusion region, the second first-conduction type region penetrating through between the first surface and the second surface of the first substrate, the second first-conduction type region being electrically coupled to the first first-conduction type layer and having an impurity concentration lower than that of the impurity diffusion region.
(15)

The photodetector according to (14) described above, in which a portion of the first electrode is embedded in the impurity diffusion region.
(16)

The photodetector according to (14) described above, in which a portion of the first electrode penetrates to the fourth surface of the second substrate.
(17)

The photodetector according to any one of (1) to (16) described above, in which the first substrate includes a substrate including germanium, silicon germanium, and indium-gallium-arsenic.
(18)

The photodetector according to any one of (1) to (17) described above, in which the second substrate includes a silicon substrate.
(19)

The photodetector according to any one of (1) to (18) described above, in which a condenser lens that condenses entering light onto the light receiving section is further provided at the first surface for each of the pixels.
(20)

A distance measurement apparatus including

an optical system,

a photodetector, and

a signal processing circuit that calculates a distance to a measurement target object on the basis of an output signal from the photodetector,

the photodetector including:
a first substrate having a first surface serving as a light receiving surface and a second surface opposed to the first surface, the first substrate having a plurality of pixels disposed in an arrayed manner, the first substrate including a light receiving section provided for each of the pixels, the light receiving section generating, through photoelectric conversion, electric charge corresponding to an amount of received light;
a second substrate disposed on a side of the second surface of the first substrate, the second substrate having a third surface directly opposed to the second surface and also having a fourth surface opposed to the third surface, the second substrate having a band gap wider than a band gap of the first substrate, the second substrate including a multiplication section provided for each of the pixels, the multiplication section applying avalanche multiplication to the electric charge generated at the light receiving section;
a first electrode provided at the first surface of the first substrate and electrically coupled to the light receiving section; and
a second electrode provided at the fourth surface of the second substrate and electrically coupled to the multiplication section.

The present application claims the benefit of Japanese Priority Patent Application No. 2021-085631 filed with the Japan Patent Office on May 20, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A photodetector comprising:
a first substrate having a first surface serving as a light receiving surface and a second surface opposed to the first surface, the first substrate having a plurality of pixels disposed in an arrayed manner, the first substrate including a light receiving section provided for each of the pixels, the light receiving section generating, through photoelectric conversion, electric charge corresponding to an amount of received light;
a second substrate disposed on a side of the second surface of the first substrate, the second substrate having a third surface directly opposed to the second surface and also having a fourth surface opposed to the third surface, the second substrate having a band gap wider than a band gap of the first substrate, the second substrate including a multiplication section provided for each of the pixels, the multiplication section applying avalanche multiplication to the electric charge generated at the light receiving section;
a first electrode provided at the first surface of the first substrate and electrically coupled to the light receiving section; and
a second electrode provided at the fourth surface of the second substrate and electrically coupled to the multiplication section.

2. The photodetector according to claim 1, wherein the first electrode is provided between the plurality of pixels, and is provided at the first surface of the first substrate in a lattice form.

3. The photodetector according to claim 1, wherein a negative voltage is applied to the first electrode.

4. The photodetector according to claim 1, further comprising an impurity diffusion layer that is provided at the first surface of the first substrate and contains a first conduction-type impurity, wherein
the first electrode is provided at the first surface of the first substrate with the impurity diffusion layer being interposed between the first electrode and the first surface.

5. The photodetector according to claim 4, wherein the impurity diffusion layer is provided over all of the first surface.

6. The photodetector according to claim 1, wherein a semiconductor layer having a band gap that falls between the band gap of the first substrate and the band gap of the second substrate is further provided between the first substrate and the second substrate.

7. The photodetector according to claim 1, wherein the multiplication section includes a first conduction-type region provided on a side of the third surface, and a second conduction-type region provided on a side of the fourth surface.

8. The photodetector according to claim 7, wherein the multiplication section further includes a first first-conduction type layer provided at or around an interface of the third surface and having an impurity concentration relatively lower than that of the first conduction-type region.

9. The photodetector according to claim 8, wherein
the second substrate further includes a separation section that electrically separates adjacent ones of the pixels from each other, and
the separation section is formed by the first first-conduction type layer extending, between the adjacent ones of the pixels, from the third surface toward the fourth surface.

10. The photodetector according to claim 1, wherein
the second substrate further includes a separation section that electrically separates adjacent ones of the pixels from each other, and
the separation section includes a material having a light-blocking property.

11. The photodetector according to claim 9, wherein
the first first-conduction type layer further includes an extended section extending within the second substrate toward a middle of the pixel, the extended section having a first opening in the middle of the pixel, and
the first conduction-type region is in contact with the extended section on the side of the fourth surface.

12. The photodetector according to claim 9, wherein the first conduction-type region is formed within the second substrate over an entire surface of the pixel so as to be in contact with the first first-conduction type layer extending from the third surface toward the fourth surface.

13. The photodetector according to claim 12, wherein the first conduction-type region has a second opening in a middle of the pixel.

14. The photodetector according to claim 8, further comprising:
an impurity diffusion region formed at the first surface of the first substrate in an embedded manner and containing a first conduction-type impurity; and
a second first-conduction type region provided around the impurity diffusion region, the second first-conduction type region penetrating through between the first surface and the second surface of the first substrate, the second first-conduction type region being electrically coupled to the first first-conduction type layer and having an impurity concentration lower than that of the impurity diffusion region.

15. The photodetector according to claim 14, wherein a portion of the first electrode is embedded in the impurity diffusion region.

16. The photodetector according to claim 14, wherein a portion of the first electrode penetrates to the fourth surface of the second substrate.

17. The photodetector according to claim 1, wherein the first substrate comprises a substrate including germanium, silicon germanium, and indium-gallium-arsenic.

18. The photodetector according to claim 1, wherein the second substrate comprises a silicon substrate.

19. The photodetector according to claim 1, wherein a condenser lens that condenses entering light onto the light receiving section is further provided at the first surface for each of the pixels.

20. A distance measurement apparatus comprising
an optical system,
a photodetector, and
a signal processing circuit that calculates a distance to a measurement target object on a basis of an output signal from the photodetector,
the photodetector including:
a first substrate having a first surface serving as a light receiving surface and a second surface opposed to the first surface, the first substrate having a plurality of pixels disposed in an arrayed manner, the first substrate including a light receiving section provided for each of the pixels, the light receiving section generating, through photoelectric conversion, electric charge corresponding to an amount of received light;
a second substrate disposed on a side of the second surface of the first substrate, the second substrate having a third surface directly opposed to the second surface and also having a fourth surface opposed to the third surface, the second substrate having a band gap wider than a band gap of the first substrate, the second substrate including a multiplication section provided for each of the pixels, the multiplication section applying avalanche multiplication to the electric charge generated at the light receiving section;
a first electrode provided at the first surface of the first substrate and electrically coupled to the light receiving section; and
a second electrode provided at the fourth surface of the second substrate and electrically coupled to the multiplication section.
